(19) United States
(12) Patent Application Publication
(10) Pub. No.: US 2014/0147984 A1
(43) Pub. Date: May 29, 2014

(54) SEMICONDUCTOR DEVICE AND METHOD OF FABRICATING THROUGH SILICON VIA STRUCTURE

(71) Applicant: UNITED MICROELECTRONICS CORP., Hsin-Chu City (TW)

(72) Inventor: Jubao Zhang, Singapore (SG)

(73) Assignee: UNITED MICROELECTRONICS CORP., Hsin-Chu City (TW)

(21) Appl. No.: 13/685,724

(22) Filed: Nov. 27, 2012

(51) Int. Cl. H01L 21/768; H01L 23/48

(52) U.S. Cl. CPC H01L 21/76898; H01L 23/481
USPC 438/401; 257/774

(57) ABSTRACT

A method of fabricating a through silicon via structure includes the following steps. At first, a substrate is provided, and a dielectric layer is formed on the substrate. Subsequently, at least one first opening is formed in the dielectric layer, and the substrate exposed by the first opening is partially removed to form at least one via opening. A conductive material layer is then formed to fill the via opening and the first opening, and the conductive material layer is planarized.

### BACKGROUND OF THE INVENTION

1. Field of the Invention

The present invention relates to a semiconductor device and a method of fabricating a through silicon via structure, and more particularly to a method of simultaneously fabricating a through silicon via structure and a conductive element within a semiconductor device, wherein the conductive element covers the through silicon via structure.

2. Description of the Prior Art

With the trend of miniaturization, diversification and constantly improving performance of portable electronic products and peripherals, a three-dimensional (3D) interconnects technique has become one of the most important aspects of current package technology. The 3D interconnects technique can achieve the desired thin structure and high integration of semiconductor devices as well as improving the abilities and capacities of a semiconductor packaged element.

The through silicon via (TSV) technique is one 3D interconnects technique which aims at solving the problems of interconnection between the wafers or dies. The TSV technique, as opposed to the conventional stack package of wire bonding type, stacks the wafers or the dies vertically to reduce the length of the conductive lines, which means that the inner connection distances can be shortened. Three-dimensional stack integrated circuits (3D stack IC) perform better in many ways, for example faster transmission and lower noise, especially for applications in CPU, flash memories and memory cards. Additionally, the TSV technique can be employed for heterogeneous integration of different ICs, such as stacking a memory on a CPU.

The TSV technique commonly includes the following steps. The via openings are drilled in the wafer by etching or by laser means, and then sequentially filled with an oxide layer formed through a thermal oxidation process which serves as an isolation layer, and conductive materials, such as copper, polysilicon or tungsten, to form via structures i.e. conductive channels used for connecting inner regions and outer regions. Finally, the wafers or the dies are thinned in order to be stacked and bonded, and then become three-dimensional stack integrated circuits (3D stack IC).

As the via openings are predetermined to be disposed on the front side of the wafer for preventing an excess oxide layer on the back side of the wafer, a cap layer is required to be formed on the back side of the wafer before the formation of the via openings. This may increase the manufacturing cost of the TSV structure process. Consequently, how to simplify the TSV process is still an important issue in the field.

### SUMMARY OF THE INVENTION

An objective of the present invention is therefore to provide a method of fabricating a through silicon via structure which can save the manufacturing cost of a semiconductor device.

According to one exemplary embodiment of the present invention, a method of fabricating a through silicon via structure includes the following steps. A substrate is provided, and a dielectric layer is formed on the substrate. Subsequently, at least one first opening is formed in the dielectric layer, and the substrate exposed by the first opening is partially removed to form at least one via opening. A conductive material layer is then formed to fill the via opening and the first opening, and the conductive material layer is planarized.

According to another exemplary embodiment of the present invention, a semiconductor device is provided. The semiconductor device includes a substrate, a dielectric layer, a plurality of conductive elements, at least one through silicon via structure and at least one alignment mark. The conductive elements are disposed in the dielectric layer on the substrate, the through silicon via structure is disposed in the substrate, and at least one of the conductive element contacts and totally covers the through silicon via structure. The alignment mark is disposed in the dielectric layer on the substrate.

The first opening and the via opening which are not simultaneously formed are filled with the conductive material layer in one process such as electro copper plating (ECP) process instead of two separate processes in order to simplify the manufacturing process of the through silicon via structure. Moreover, a liner layer between the conductive material layer and the substrate is only formed on the front surface of the substrate, so that no excess liner layer will be formed on the back side of the substrate, and the conventional cap layer process can be omitted. Furthermore, during the formation of the first opening, at least a second opening can be simultaneously formed in the dielectric layer without penetrating the substrate, and the second opening may serve as an alignment mark on the substrate. This means etching through different materials (the dielectric layer and the substrate) can be avoided, and an appropriate profile of the alignment mark can thereby be obtained.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 6 are schematic diagrams illustrating a method for fabricating a through silicon via structure according to a preferred exemplary embodiment of the present invention.

FIG. 7 is a schematic planar view illustrating a semiconductor device according to a preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

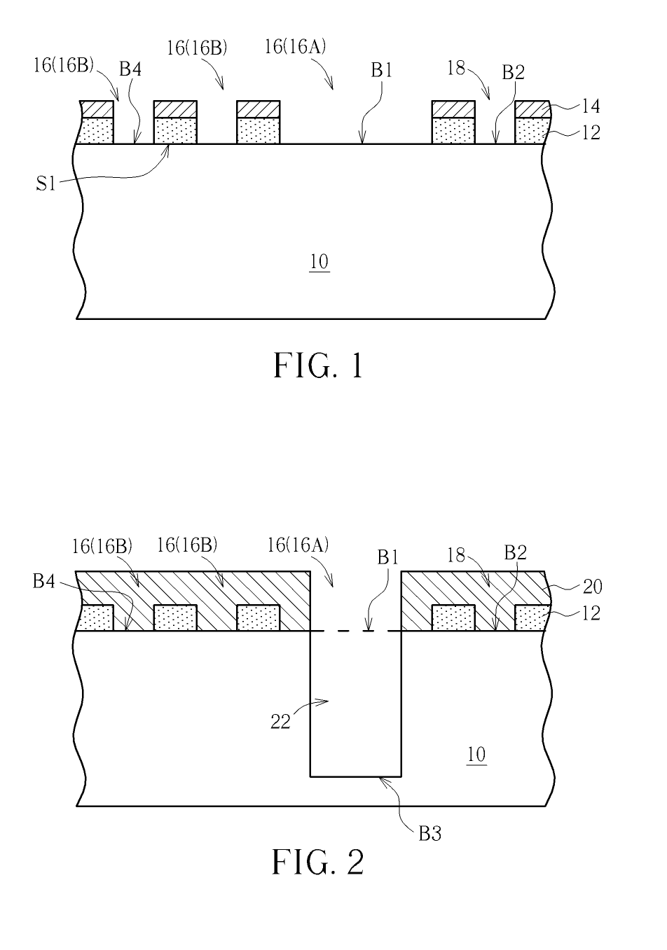

Please refer to FIG. 1 through FIG. 6, which are schematic diagrams illustrating a method for fabricating a through silicon via structure according to a preferred exemplary embodiment of the present invention. It should be noted that the drawing size of the figures is not a real scale ratio; rather, it is merely intended as a schematic for reference. As shown in FIG. 1, a substrate 10 is provided, and a dielectric layer 12 is formed on the substrate 10. The substrate 10 may be a semiconductor substrate composed of silicon, gallium arsenide (GaAs), silicon on insulator (SOI) layer, epitaxial layer, SiGe layer or other semiconductor materials. The dielectric layer 12 made of dielectric materials may include an oxide layer made of silicon oxynitride (SiON), silicon oxide (SiO), or tetraethylorthosilicate (TEOS) and formed through a thermal oxidation process or a deposition process such as a chemical vapor deposition (CVD) process or an atomic layer deposition (ALD) process, but is not limited thereto. Furthermore, the dielectric layer 12 includes a single layered structure, or a multi-layered structure made of silicon oxynitride and silicon oxide, or another composition.

Subsequently, a photolithography and etching process is performed to pattern the dielectric layer 12, and at least one first opening 16 and at least one second opening 18 are formed in the dielectric layer 12. The photolithography and etching process may include the following steps. A patterned photoresist layer is used as a mask 14, and a part of the dielectric layer 12 exposed by the mask 14 is removed through an etching process, for example, an anisotropic etching process such as a reactive-ion-etching (RIE) process. The first openings 16 and the second opening 18 are thereby formed in the dielectric layer 12, and finally the mask 14 is removed. In a modification, a patterned photoresist layer (not shown) and a material layer (not shown) are formed sequentially on the dielectric layer 12, and the patterns of the patterned photoresist layer may be previously transferred into the material layer, and the patterned material layer may serves as a mask 14 to remove a part of the dielectric layers 12.

In this exemplary embodiment, the first openings 16 and the second opening 18 are simultaneously formed through the same mask 14 in the same photolithography and etching process, where a depth of the first opening 16 is substantially the same as a depth of the second opening 18, but is not limited thereto. The mask 14 disposed on the dielectric layer 12 may include the pattern of passive components such as a resistor, capacitor, diode, inductor, etc. and the pattern of the alignment mark predetermined to be formed in the later formed semiconductor device. More specifically, the pattern of passive components could be used to define a pattern of the first openings 16, and the pattern of alignment mark could be used to define a pattern of the second opening 18. Furthermore, the etching process performed on the dielectric layer 12 may stop as the substrate 10 is exposed; in other words, the formed first openings 16 and the formed second opening 18 preferably do not penetrate the substrate 10. However, due to the chemical substances selected for the etching process and the over etching time selected to reassure full removal of the dielectric layer 12 originally in the first openings 16 and the second opening 18, the substrate 10 exposed by the first openings 16 and second opening 18 may be slightly consumed. Here, the depth of the slightly consumed substrate is less than 5% of the depth of the to-be-formed via opening 22. A bottom B1/B4 of the first opening 16A/16B and a bottom B2 of the second opening 18 respectively include an exposed surface S1 of the substrate 10, in which the exposed surface S1 may be the surface of the substrate 10 originally contacting the dielectric layer 12 or a surface of the substrate 10 exposed after a thin layer of the substrate is consumed. It should be appreciated that, as the second opening 18 is totally formed in the dielectric layer 12 without penetrating the substrate 10, etching through different materials such as the dielectric layer 12 and the substrate 10 can be avoided, and an appropriate profile of the second opening 18 serving as the alignment mark can be obtained.

In another exemplary embodiment, an additional etching process can be further performed to remove the substrate 10 exposed by the first openings 16 in order to increase a depth of the first openings 16, and the second opening 18 may be covered by a mask or the process conditions such as the aperture of the second opening 18 may be adjusted. This means that the first openings 16 may extend into the substrate 10, i.e. the bottom of the first opening 16 may be located lower than the bottom of the second opening 18. In other words, the depth of the first opening 16 may be substantially different from the depth of the second opening 18. Furthermore, the widths of the first openings 16 are not limited to be the same: each of the first openings 16 may have its respective width, i.e. a width of the first opening 16A could be substantially different from a width of the first opening 16B.

As shown in FIG. 2, another photolithography and etching process is performed to partially remove the substrate 10 exposed by the first opening 16A to form at least one via opening 22, and the second opening 18 may serve as an alignment mark in this process. The method of forming the via opening 22 after the formation of the first openings 16 includes the following steps. Another mask 20 such as a patterned photoresist layer or a patterned material layer is formed to fill the second opening 18, the first openings 16B and cover a part of the substrate 10 exposed by the first opening 16A. Subsequently, an etching process is performed to remove a part of the substrate 10 exposed by the first opening 16A to form the via opening 22; in other words, the via opening 22 can be formed in the substrate 10. Finally, the mask 20 is removed. In this exemplary embodiment, a width of the via opening 22 is substantially smaller than a width of the first opening 16A; therefore, the first opening 16A can totally overlap the via opening 22, while the other first opening 16B and the second opening 18 do not overlap the via opening 22. More specifically, a cross-sectional width of the via opening 22 is substantially smaller than a cross-sectional width of the first opening 16A, the original bottom B1 of the first opening 16A overlaps a bottom B3 of the via opening 22, and the original bottom B4 of the first opening 16B and the bottom B2 of the second opening 18 do not overlap the bottom B3 of the via opening 22.

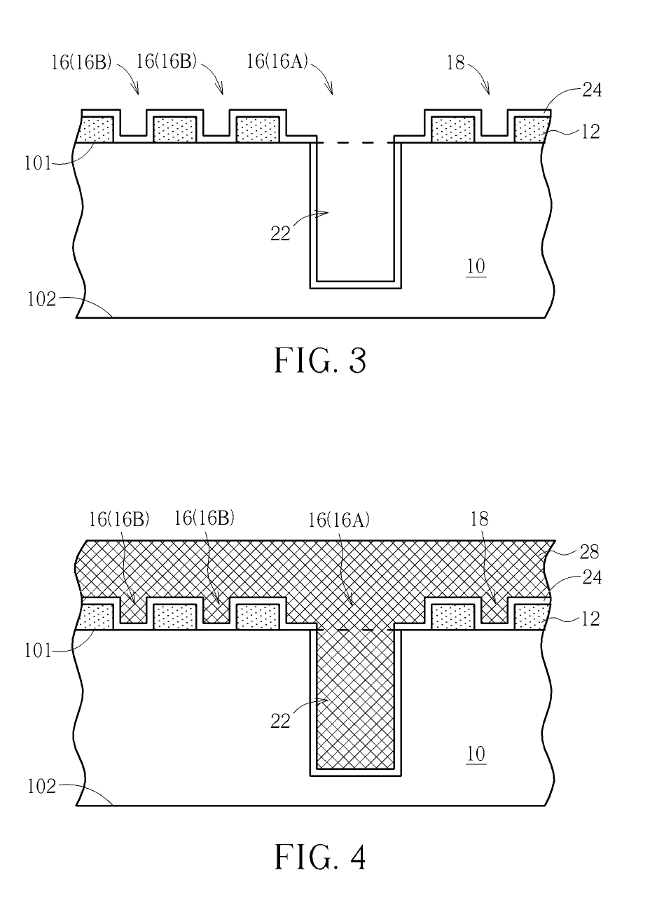

As shown in FIG. 3, a liner layer 24 is formed on the dielectric layer 12. The liner layer 24 conformally covers the dielectric layer 12, and the substrate 10 exposed by the first opening 16, the second opening 18 and the via opening 22. The liner layer 24 conformally covers the sidewalls of the first opening 16, the sidewalls of the via opening 22 and the bottom of the via opening 22 as a consecutive layer, and the via opening 22 is not filled up with the liner layer 24. The liner layer 24 may include dielectric materials such as silicon oxide (SiO). Furthermore, the method of forming the liner layer 24 preferably includes a chemical vapor deposition (CVD) process instead of a thermal oxidation process. Therefore, the liner layer 24 can only be formed on the front surface 101 of the substrate 10, and is not formed on the back side 102 of the substrate 10. Accordingly, the step of forming a cap layer used to prevent the formation of the excess liner layer 24 on the back side 102 of the substrate 10 can be omitted, which is beneficial for simplifying the manufacturing process. Moreover, the second opening 18 can be filled up with the liner layer 24 or not according to process requirements.

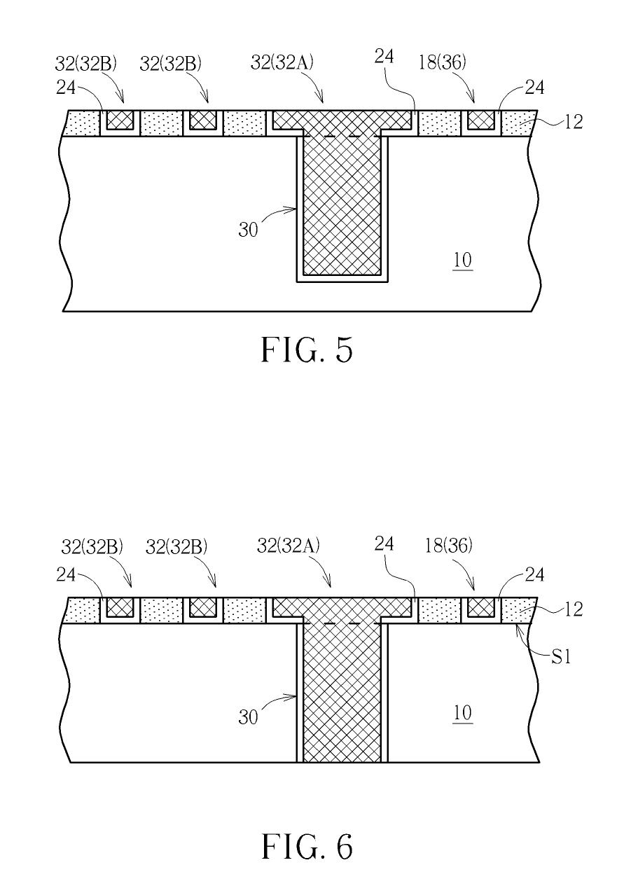

As shown in FIG. 4, a conductive material layer 28 is formed to fill the via opening 22 and the first openings 16 (including the first opening 16A and the first openings 16B). The conductive material layer 28 may include, for example, copper (Cu), tungsten (W), aluminum (Al) or other suitable materials. The filling of the conductive material layer 28 may be accomplished through, for example, electroplating, sputtering, CVD, electroless plating/electroless grabbing, or other suitable processes. Before forming the conductive material layer 28, a barrier layer (not shown) and a seed layer (not shown) can be sequentially formed on the dielectric layer 12 before forming the conductive material layer 28. A material of the barrier layer may include, for example, tantalum (Ta), tantalum nitride (TaN), titanium (Ti), titanium nitride (TiN) or a combination thereof. As shown in FIG. 5, the conductive material layer 28 on the front surface of the substrate 10 is planarized to expose the dielectric layer 12 through a chemical mechanical polishing (CMP) process. Accordingly, a through silicon via structure 30 and a plurality of conductive components 32 can be completed, and the conductive components 32 may serve as passive components. Thereafter, a CMP process may be further performed on the back side of the substrate 10 to thin the substrate 10 until the conductive material layer 28 of the through silicon via structure 30 is exposed. In other words, the substrate 10 neighboring the bottom B3 of the via opening 22 may be removed, as shown in FIG. 6.

It should be appreciated that the through silicon via structure 30 and the conductive components 32 are simultaneously formed in the same process of forming the conductive material layer 28, instead of two separate processes being used for respectively filling conductive materials into the first openings 16 and the via opening 22. Accordingly, the manufacturing process can be simplified. In this exemplary embodiment, the openings including the first openings 16 and the via opening 22 are formed in different steps: for example, the first openings 16 are formed before the via opening 22, and then the first openings 16 and the via opening 22 are all simultaneously filled with the conductive material layer 28 through the same electro copper plating (ECP) process, in which at least one of the conductive components 32 such as the conductive component 32A may directly cover and contact the through silicon via structure 30, and the other conductive components 32 such as the conductive component 32B do not overlap the through silicon via structure 30.

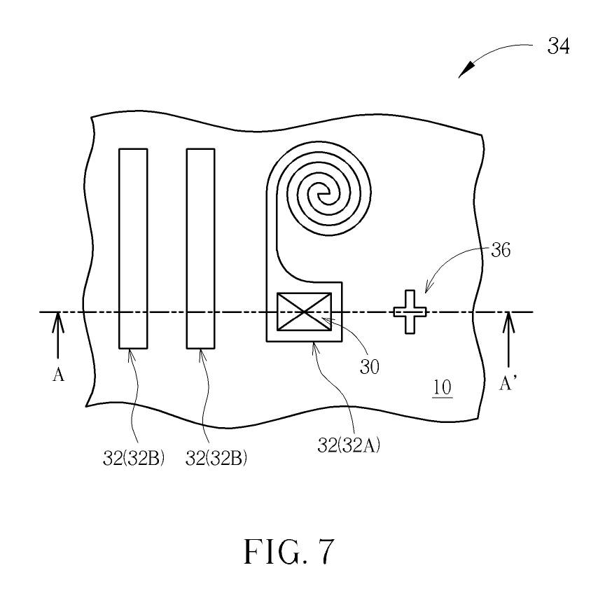

Please refer to FIG. 6 and FIG. 7 together. FIG. 7 is a schematic planar view illustrating a semiconductor device according to a preferred exemplary embodiment of the present invention. FIG. 6 is a cross-sectional view illustrating the semiconductor device taken along the line AA′ of FIG. 7 according to the preferred exemplary embodiment of the present invention. To simplify the explanation, components in FIG. 7 which are the same as components previously described will be referred to by the same numerals. As shown in FIG. 7, the semiconductor device 34 includes a plurality of conductive elements 32, at least one through silicon via structure 30 and at least one alignment mark 36. Furthermore, the liner layer 24 disposed between the conductive element 32 and the dielectric layer 12 and between the through silicon via structure 30 and the substrate 10 may cover the alignment mark 36. The conductive elements 32 and the alignment mark 36 are disposed in the dielectric layer 12 on the substrate 10. The alignment mark 36 (the second opening 18) preferably do not penetrate the substrate 10. The alignment mark 36 may be cross-shaped for alignment in later processes, but is not limited thereto. The conductive elements 32 formed by filling the conductive materials into the first openings 16 can serve as passive components such as a resistor, capacitor, diode, inductor, etc. The shape, the size and the number of the conductive elements 32 are not limited, except for the disposition of the conductive elements 32. The conductive elements 32 include at least one of the conductive elements 32 overlapping the through silicon via structure 30 disposed in the substrate 10; in other words, at least one of the conductive elements 32 such as the conductive element 32A directly contacts and totally covers the through silicon via structure 30. Furthermore, the conductive element 32A is not limited to serve as passive component. In other aspects, the conductive element 32A could serve as a redistribution layer (RDL). The through silicon via structure 30 formed by filling the conductive materials into the via opening 22 is disposed in the substrate 10 and overlapped by the conductive component 32A. The through silicon via structure 30 can be a through silicon via structure within a silicon interposer, which is applied to electrical connection between layers of a chip stack.

In conclusion, the first opening and the via opening not simultaneously formed are filled with the conductive material layer in one process such as electro copper plating (ECP) process instead of two separate processes in order to simplify the manufacturing process of the through silicon via structure. Moreover, a liner layer between the conductive material layer and the substrate is only formed on the front surface of the substrate; therefore, no excess liner layer may be formed on the back side of the substrate, and the conventional cap layer process can be omitted. Furthermore, during the formation of the first opening, at least a second opening can be simultaneously formed in the dielectric layer without penetrating the substrate, and the second opening may serve as an alignment mark on the substrate. Therefore, etching through different materials (the dielectric layer and the substrate) can be avoided, and an appropriate profile of the alignment mark can be obtained.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating a through silicon via structure, comprising:
providing a substrate;
forming a dielectric layer on the substrate;
forming at least one first opening in the dielectric layer;
partially removing the substrate exposed by the first opening to form at least one via opening;
forming a conductive material layer to fill the via opening and the first opening; and
planarizing the conductive material layer.

2. The method of fabricating a through silicon via structure according to claim 1, wherein a width of the via opening is substantially smaller than a width of the first opening.

3. The method of fabricating a through silicon via structure according to claim 1, wherein the first opening comprises a pattern of passive component.

4. The method of fabricating a through silicon via structure according to claim 1, wherein the first opening does not penetrate the substrate.

5. The method of fabricating a through silicon via structure according to claim 4, wherein a bottom of the first opening comprises an exposed surface of the substrate.

6. The method of fabricating a through silicon via structure according to claim 1, wherein the first opening extends into the substrate.

7. The method of fabricating a through silicon via structure according to claim 1, further comprising forming at least one second opening in the dielectric layer.

8. The method of fabricating a through silicon via structure according to claim 7, wherein the second opening does not penetrate the substrate.

9. The method of fabricating a through silicon via structure according to claim 7, wherein the second opening is formed before forming the via opening.

10. The method of fabricating a through silicon via structure according to claim 7, wherein the second opening does not overlap the via opening.

11. The method of fabricating a through silicon via structure according to claim 7, wherein the first opening and the second opening are formed simultaneously, and a depth of the first opening is substantially the same as a depth of the second opening.

12. The method of fabricating a through silicon via structure according to claim 7, wherein the second opening comprises an alignment mark.

13. The method of fabricating a through silicon via structure according to claim 1, further comprising forming a liner layer on the dielectric layer before forming the conductive material layer, wherein the liner layer conformally covers the dielectric layer and the substrate exposed by the first opening and the via opening.

14. The method of fabricating a through silicon via structure according to claim 13, wherein the method of forming the liner layer comprises a chemical vapor deposition (CVD) process.

15. The method of fabricating a through silicon via structure according to claim 1, further comprising forming a barrier layer and a seed layer on the dielectric layer before forming the conductive material layer.

16. A semiconductor device, comprising:
a plurality of conductive elements disposed in a dielectric layer on a substrate;
at least one through silicon via structure disposed in the substrate, wherein at least one of the conductive elements contacts and totally covers the through silicon via structure; and
at least one alignment mark disposed in the dielectric layer on the substrate.

17. The semiconductor device according to claim 16, wherein the alignment mark does not penetrate the substrate.

18. The semiconductor device according to claim 16, further comprising a liner layer disposed between the conductive element and the dielectric layer and between the through silicon via structure and the substrate, wherein the liner layer covers the alignment mark.

19. The semiconductor device according to claim 16, wherein the conductive elements comprises passive components.
